(19) United States
(12) Patent Application Publication
(10) Pub. No.: US 2010/0290515 A1
(43) Pub. Date: Nov. 18, 2010

(54) Multi-Band Gain Adaptation for Receiver Equalization Using Approximate Frequency Separation

(76) Inventors: Xingdong Dai, Whitehall, PA (US); Wenyi Jin, Milpitas, CA (US); Max J. Olsen, Mertztown, PA (US); Geoffrey Zhang, Allentown, PA (US)

Correspondence Address: Ryan, Mason & Lewis, LLP, 90 Forest Avenue, Locust Valley, NY, 11560, US

(21) Appl. No.: 12/467,507

(22) Filed: May 18, 2009

(51) Int. Cl. H03H 7/40

(52) U.S. Cl. 375/232

(57) ABSTRACT

A receiver comprises equalization circuitry implementing at least first and second gain adaptation loops associated with respective first and second frequency bands. The equalization circuitry in one aspect is operative to identify a pattern in a portion of a received serial data stream, and to perform gain adaptation for the receiver utilizing a particular one of the gain adaptation loops responsive to the identified pattern. For example, the gain adaptation may be performed utilizing a low frequency gain adaptation loop if the detected pattern is of a first type generally associated with a low frequency band, and may be performed utilizing a high frequency gain adaptation loop if the detected pattern is of a second type generally associated with a high frequency band. In other aspects, the first and second gain adaptation loops may be activated in a particular serial order or in parallel.

### FIELD OF THE INVENTION

The present invention relates generally to communication systems, and more particularly to receiver equalization circuitry utilized in such systems.

### BACKGROUND OF THE INVENTION

Many communication system receivers incorporate equalization circuitry. For example, equalization circuitry is commonly utilized in a receiver of a high-speed serializer/deserializer (SerDes) device to mitigate the effects of inter-symbol interference (ISI) caused by transmission over a bandwidth limited serial link. Such equalization circuitry may comprise a decision feedback equalizer (DFE), a linear equalizer (LEQ), or other type of equalizer, as well as combinations of multiple equalizers. Compared to a DFE, an LEQ typically exhibits reduced complexity, higher operating speed, lower power, and smaller circuit area.

It is known to make an LEQ tunable in order to accommodate various operating scenarios. An example of such an arrangement is disclosed in J. Choi et al., “A 0.18-m CMOS 3.5-Gb/s continuous-time adaptive cable equalizer using enhanced low frequency gain control method,” IEEE Journal of Solid-State Circuits, pp. 419-425, Vol. 39, No. 3, March 2004. However, in arrangements such as this, it may be necessary to manually set certain LEQ parameters in the factory, which requires additional testing and thereby increases the cost of the associated device. Also, the use of these pre-set parameters can lead to sub-optimal performance in the presence of typical variations in environmental conditions, such as voltage, temperature and link characteristics, that can arise when the device is deployed in the field.

Other examples of conventional LEQ arrangements are disclosed in U.S. Patent Application Publication No. 2007/0018694, entitled “High-Speed CML Circuit Design,” which is commonly assigned herewith and incorporated by reference herein, and J. Chen et al., “Electrical backplane equalization using programmable analog zeros and folded active inductors,” IEEE Transactions on Microwave Theory and Techniques, pp. 1459-1466, Vol. 55, No. 7, July 2007.

Known SerDes devices that incorporate adaptive LEQs include the HyperPHY™ and GigaBlaze™ families of SerDes devices commercially available from LSI Corporation of Milpitas, Calif., U.S.A.

Although equalization circuitry of the type mentioned above can provide significant ISI reduction in many practical applications, a need remains for further enhancements in the design of LEQs and other types of equalizers.

### SUMMARY OF THE INVENTION

Illustrative embodiments of the present invention meet the above-noted need by providing techniques for multi-band gain adaptation in an LEQ using an approximate frequency separation approach.

In accordance with one aspect of the invention, a receiver includes equalization circuitry implementing at least first and second gain adaptation loops associated with respective first and second frequency bands. The equalization circuitry is operative to identify a pattern in a portion of a received serial data stream, and to perform gain adaptation for the receiver utilizing a particular one of the gain adaptation loops responsive to the identified pattern. For example, the gain adaptation may be performed utilizing a low frequency gain adaptation loop if the detected pattern is of a first type generally associated with a low frequency band, and may be performed utilizing a high frequency gain adaptation loop if the detected pattern is of a second type generally associated with a high frequency band.

In accordance with another aspect of the invention, the equalization circuitry comprises an equalizer configured to receive the serial data stream, a latch array having an input coupled to an output of the equalizer, first and second gain adaptation elements arranged within the respective first and second gain adaptation loops and coupled between an output of the latch array and respective control inputs of the equalizer, and selection circuitry configured to selectively activate at least one of the first and second gain adaptation elements responsive to a particular operating mode of the equalization circuitry.

For example, the equalization circuitry may be operable in a serial equalization mode in which the first and second gain adaptation elements are activated in a particular serial order. There may be at least two distinct serial equalization modes, including a first serial equalization mode in which the first gain adaptation element is activated to allow the first gain adaptation loop to perform gain adaptation for the first frequency band prior to the second gain activation element being activated to allow the second gain adaptation loop to perform gain adaptation for the second frequency band, and a second serial equalization mode in which the second gain adaptation element is activated to allow the second gain adaptation loop to perform gain adaptation for the second frequency band prior to the first gain activation element being activated to allow the first gain adaptation loop to perform gain adaptation for the first frequency band.

The equalization circuitry may also be operable in a parallel equalization mode in which the first gain adaptation element is activated to allow the first gain adaptation loop to perform gain adaptation for the first frequency band substantially simultaneously with the second gain activation element being activated to allow the second gain adaptation loop to perform gain adaptation for the second frequency band.

Other operating modes are possible. For example, the equalization circuitry may be further operable in a single-band equalization mode in which only a designated one of the first and second gain adaptation elements is activated to allow its corresponding gain adaptation loop to perform gain adaptation for the associated frequency band.

The first and second gain adaptation elements may comprise respective first and second gain adaptation state machines, portions of which may be implemented in the form of software stored in a memory and executed by a processor.

The gain adaptation performed by a given one of the first and second gain adaptation loops is responsive to detection of one or more designated patterns in the serial data stream. For example, the first and second gain equalization elements may apply respective first and second sets of pattern identification rules to one or more portions of the serial data stream as stored in the latch array in order to detect patterns associated with the respective first and second frequency bands. The first set of rules utilized by the first gain adaptation element to detect patterns associated with the first frequency band may include at least one of a low frequency exact rule and first and second low frequency approximate rules. Similarly, the second set of rules utilized by the second gain adaptation element to detect patterns associated with the second frequency band may include at least one of a high frequency exact rule and first and second high frequency approximate rules. Numerous other types of pattern identification rules may be used to provide approximate frequency separation between the first and second gain adaptation loops.

The illustrative embodiments provide improved receiver equalization relative to conventional approaches, while avoiding the costs and performance limitations commonly associated with manual tuning of LEQ parameters. For example, the self-adaptive equalization provided in the illustrative embodiments can allow a given SerDes or other communication device to operate at a higher data rate than would otherwise be possible.

### BRIEF DESCRIPTION OF THE DRAWINGS

FIG. 1 is a block diagram of a communication system in an illustrative embodiment of the invention.

FIG. 2 shows a more detailed view of a receiver of the FIG. 1 system.

FIG. 3 is a schematic diagram of equalization circuitry of the FIG. 2 receiver.

FIGS. 4 through 7 are flow diagrams illustrating different gain adaptation configurations of the equalization circuitry of FIG. 3.

FIGS. 8A and 8B show exemplary linear equalizers that may be implemented in the FIG. 3 equalization circuitry.

FIGS. 9 and 10 show respective variable resistance and variable capacitance elements of the linear equalizers of FIG. 8.

FIG. 11 shows exemplary frequency response curves for the linear equalizer of FIG. 8B.

FIG. 12 is a plot of an exemplary pseudorandom pattern with low frequency bits marked using an approximate rule in an illustrative embodiment.

FIG. 13 is a diagram illustrating the operation of an eye latch array of the FIG. 3 equalization circuitry in an illustrative embodiment.

FIGS. 14 and 15 are flow diagrams for respective positive polarity and negative polarity low frequency gain adaptation in the FIG. 3 equalization circuitry.

FIG. 16 is a flow diagram for high frequency gain adaptation in the FIG. 3 equalization circuitry.

FIGS. 17-26 are eye diagrams illustrating improvements attributable to equalization in different gain adaptation configurations of the FIG. 3 equalization circuitry.

### DETAILED DESCRIPTION OF THE INVENTION

The invention will be illustrated herein in conjunction with exemplary communication systems, receivers and equalization circuitry. It should be understood, however, that the invention is more generally applicable to other types of communication systems and receivers, and may be implemented using other arrangements of equalization circuitry. For example, the techniques disclosed herein can be adapted in a straightforward manner for use in any communication system comprising one or more serial links in which it is desirable to provide improved equalization so as to facilitate operation at high data rates.

FIG. 1 shows a portion of a communication system 100 in which the present invention is implemented. The system 100 comprises a first node 102 and a second node 104. The two nodes are connected by a bidirectional serial data channel transmission medium 105, also referred to herein as a “link.” The first node 102 comprises a transmitter 102T configured for communication with a receiver 104R of the second node 104, and further comprises a receiver 102R configured for communication with a transmitter 104T of the second node 104.

The nodes 102 and 104 may be configured to communicate over serial link 105 in accordance with a known serial communication standard, such as Fibre Channel. Fibre Channel is an American National Standards Institute (ANSI) standard specifying a bidirectional serial data channel, structured for high performance capability. Physically, the Fibre Channel may be viewed as an interconnection of multiple communication points, called N_Ports, interconnected by a link comprising a switching network, called a fabric, or a point-to-point link. Fibre is a general term used to cover all physical media types supported by the Fibre Channel standard, such as optical fibre, twisted pair, and coaxial cable. Additional details regarding these and other aspects of Fibre Channel can be found in the ANSI Fibre Channel standard documents, including the FC-PH, FC-FS, FC-AL-2, FC-PI, FC-DA, FC-MI and FC-LS documents, all of which are incorporated by reference herein.

It is to be appreciated, however, that the present invention can be implemented in communication systems that include other types of serial links, including, for example, serial links configured in accordance with standards such as InfiniBand, IEEE 1394, PCI-Express, Ethernet, Serial Attached SCSI (SAS), Serial Advanced Technology Attachment (SATA), SONET/SDH, etc.

A given one of the nodes 102 or 104 may be configured to operate as a backplane in an illustrative embodiment of the invention. Such a backplane may be used, for example, to interconnect multiple switches, application-specific integrated circuits (ASICs), hard disk drives (HDDs) or other system elements.

The nodes 102, 104 may be viewed as examples of what are more generally referred to herein as communication devices. Such devices may comprise, for example, a SerDes device of the type previously mentioned herein.

A given node may comprise or be part of another type of communication device, such as a router, switch, computer, server, etc. Conventional aspects of such communication devices are well known and therefore not described in detail herein.

Although only two nodes are shown in FIG. 1, other embodiments of the invention may include many more nodes, in any desired configuration.

Also, a full duplex arrangement of the type illustrated in FIG. 1 is not a requirement of the present invention. In other embodiments, for example, transmitter 104T may communicate with a receiver in a node other than node 102, or transmitter 102T may communicate with a receiver in a node other than node 104.

As will be described in greater detail below, the receivers 102R and 104R in the FIG. 1 embodiment are configured to incorporate equalization circuitry comprising an LEQ with multi-band gain adaptation based on an approximate frequency separation approach. More specifically, pattern identification is used in this embodiment to separate a high frequency gain adaptation loop from a low frequency gain adaptation loop. The high and low frequency adaptations are independent of each other and can be performed either in series or in parallel, resulting in a very flexible architecture. This exemplary multi-band gain adaptation exhibits improved performance relative to existing adaptation techniques.

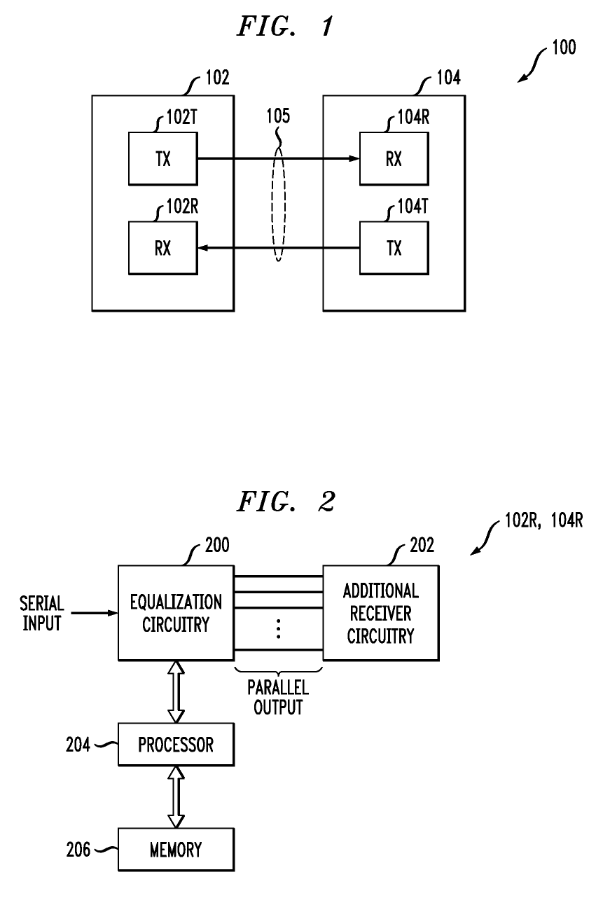

FIG. 2 shows a more detailed view of a given one of receivers 102R and 104R in the present embodiment. Each such receiver comprises equalization circuitry 200 which receives an input serial data stream and provides corresponding parallel output streams to additional receiver circuitry 202. The additional receiver circuitry 202 may comprise, for example, signal processing circuitry, switching circuitry, or other types of conventional circuitry typically found in a communication system receiver. Such conventional circuitry, being well understood by those skilled in the art, will not be described in detail herein.

Also included in the receiver 102R or 104R is a processor 204 coupled to a memory 206. The processor 204 is coupled to the equalization circuitry 200. The memory 206 may be configured to store one or more parameters of the above-noted gain adaptation loops. Such loops and other portions of the equalization circuitry 200 may be operated at least in part under control of the processor. The memory 206 may therefore store program code that is executed by the processor to implement at least a portion of an equalization process carried out by the receiver. The memory is an example of what is more generally referred to herein as a computer-readable medium or other type of computer program product having computer program code embodied therein, and may comprise, for example, electronic memory such as RAM or ROM, magnetic memory, optical memory, or other types of storage devices in any combination. The processor 204 may comprise a microprocessor, CPU, ASIC, FPGA or other type of processing device, as well as portions or combinations of such devices. In other embodiments, at least a portion of the equalization circuitry may be implemented within the processor. Alternatively, the processor may implement at least a portion of the equalization circuitry. It should therefore be apparent that an equalization technique in accordance with the present invention may be implemented using various combinations of hardware, software and firmware.

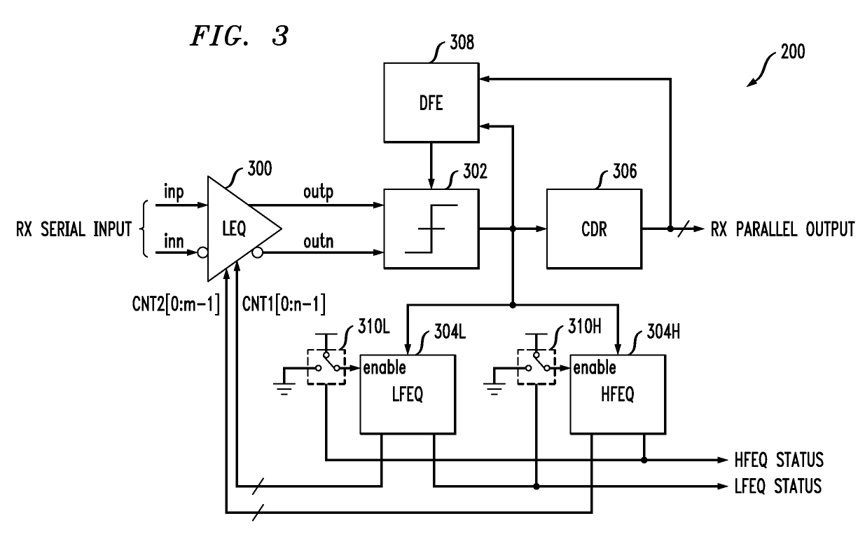

The operation of the equalization circuitry 200 will now be described in greater detail with reference to FIGS. 3 through 26. For clarity, this description will be separated into sections, denoted Section 1 through Section 6 below. It is to be appreciated that these sections describe illustrative embodiments of the invention, and alternative embodiments need not include the particular elements or features described.

### Section 1. Dual-Band Adaptation Architecture

An illustrative dual-band embodiment of the equalization circuitry 200 of FIG. 2 is shown in FIG. 3. In this embodiment, the equalization circuitry 200 comprises an analog LEQ 300 that has an adjustable low frequency gain and an adjustable high frequency gain. The LEQ has a differential serial input comprising a positive input signal line (inp) and a negative input signal line (inn), and a differential serial output comprising a positive output signal line (outp) and a negative output signal line (outn). The serial output signal lines of the LEQ are coupled to respective inputs of an eye latch array 302, which is also referred to herein as a “slicer.”

The eye latch array 302 is assumed without limitation to utilize a 2-UI sampling arrangement, where UI denotes unit interval. In a so-called “bang-bang” type of eye latch array, an example of which is illustrated in FIG. 13, a 2-UI sampling arrangement will require two data latches and two transition latches, for a total of four latches, not including any roaming latch. Other embodiments may use other types of sampling arrangements, including 3-UI, 4-UI, 5-UI, etc. However, using a sampling arrangement with a larger UI value will require that the eye latch array include more latches, and will therefore tend to increase device power and size. The total number of latches required for these other sampling arrangements, if implemented using a bang-bang type eye latch array, will generally be two times the UI value. Thus, a 3-UI sampling arrangement will require 6 latches, a 4-UI sampling arrangement will require 8 latches, and so on. It should be noted that other types of eye latch arrays may be used, such as baud rate type latch arrays, which generally do not require transition latches.

The equalization circuitry 200 further comprises a low frequency equalization (LFEQ) state machine 304L, a high frequency equalization (HFEQ) state machine 304H, a clock-and-data recovery (CDR) unit 306, and a decision feedback equalizer (DFE) 308. The LFEQ and HFEQ state machines 304L and 304H have respective enable switches 310L and 310H associated therewith. The switches 310L and 310H apply enable signals to respective enable inputs of the LFEQ and HFEQ state machines 310L and 310H, with each such switch being controlled responsive to a status signal generated by the opposite state machine. That is, the switch 310L is controlled by a status signal generated by the HFEQ state machine 310H, and the switch 310H is controlled by a status signal generated by the LFEQ state machine 310L.

The switches 310L and 310H may be viewed as examples of what is more generally referred to herein as “selection circuitry.” Such selection circuitry in other embodiments may be incorporated into other elements of the equalization circuitry 200, such as one or both of the state machines 304L and 304H.

The CDR 306 and DFE 308 may each be configured in a well-known conventional manner, and their operation will therefore not be described in detail herein. In one possible alternative embodiment, the DFE 308 may be eliminated, such that the equalization circuitry comprises only a single equalizer, namely, the LEQ 300.

The output of the eye latch array 302 is coupled to respective inputs of the LFEQ state machine 304L, the HFEQ state machine 304H, the CDR 306 and the DFE 308. The LFEQ and HFEQ state machines 304L and 304H are also referred to herein as simply the LFEQ and the HFEQ, respectively. The LFEQ and HFEQ are configured in the present embodiment to implement the above-noted approximate frequency separation approach. This approach utilizes pattern identification to separate a high frequency gain adaptation loop from a low frequency gain adaptation loop. The low frequency gain adaptation loop comprises the LEQ 300, the eye latch array 302 and the LFEQ 304L, with the LFEQ providing an n-bit control signal CNT1 to a first control input of the LEQ. The high frequency gain adaptation loop comprises the LEQ 300, the eye latch array 302 and the HFEQ 304H, with the HFEQ providing an m-bit control signal CNT2 to a second control input of the LEQ.

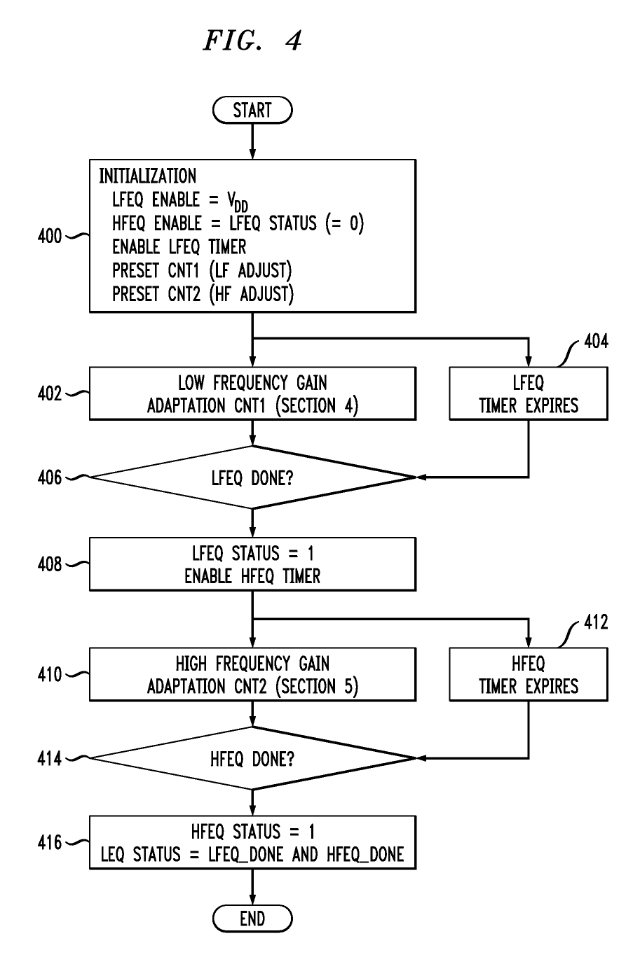

The two gain adaptation loops in the present embodiment are independent of each other, thus permitting at least four useful adaptation configurations, referred to herein as serial low frequency and high frequency adaptation (SLHA), serial high frequency and low frequency adaptation (SHLA), parallel adaptation (PA), and high frequency only adaptation (HA). The SLHA, SHLA, PA and HA configurations are illustrated in the respective flow diagrams of FIGS. 4 through 7. It should be noted that other configurations are possible. For example, one can enable the FIG. 3 equalization circuitry to perform low frequency only adaptation (LA), but since a typical primary purpose of LEQ is to compensate high-frequency loss, the LA configuration will likely have more limited application. These various gain adaptation configurations may be viewed as illustrative examples of what are more generally referred to herein as “operating modes” of the equalization circuitry.

It should be noted that the use of two separate gain adaptation frequency bands in the FIG. 3 embodiment is by way of illustrative example only. Other embodiments of the invention may have only a single gain adaptation frequency band, or more than two gain adaptation frequency bands. Thus, embodiments of the invention may have, for example, high, medium and low frequency bands, or multiple low frequency bands. Each such band will generally have a corresponding gain adaptation loop. The term “frequency band” as used herein is intended to be construed generally, and should not be viewed as requiring any particular rigid boundaries.

It should also be appreciated that the particular arrangement of circuit elements shown in FIG. 3 is by way of illustrative example only. Equalization circuitry in accordance with a given embodiment of the present invention may include other elements in addition to or in place of those specifically shown, including one or more elements of a type commonly found in a conventional implementation of such circuitry.

The general operation of the SLHA, SHLA, PA and HA gain adaptation configurations of the FIG. 3 equalization circuitry 200 will now be described with reference to the respective flow diagrams of FIGS. 4 through 7.

FIG. 4 illustrates the operation of the SLHA gain adaptation configuration. The process begins with initialization in step 400. As part of this initialization, the LFEQ enable signal is set to positive supply voltage V_{DD}, the HFEQ enable signal is set to the LFEQ status, an LFEQ timer is started, and the control signal CNT1 is adjusted to a preset value. The LFEQ status is initially set to a logic zero value.

In step 402, the low frequency gain adaptation is performed using control signal CNT1 as described in greater detail in Section 4 below. Upon completion of the low frequency gain adaptation in step 402, or upon expiration of the LFEQ timer in step 404, the LFEQ portion of the process is determined to be complete in step 406, and the process then moves to step 408, where the LFEQ status is set to a logic one value, and an HFEQ timer is enabled.

In step 410, the high frequency gain adaptation is performed using control signal CNT2 as described in greater detail in Section 5 below. Upon completion of the high frequency gain adaptation in step 410, or upon expiration of the HFEQ timer in step 412, the HFEQ portion of the process is determined to be complete in step 414, and the process then moves to step 416, where the HFEQ status is set to a logic one value, and an LEQ status indicator is set to indicate that both the LFEQ and HFEQ portions of the process are complete.

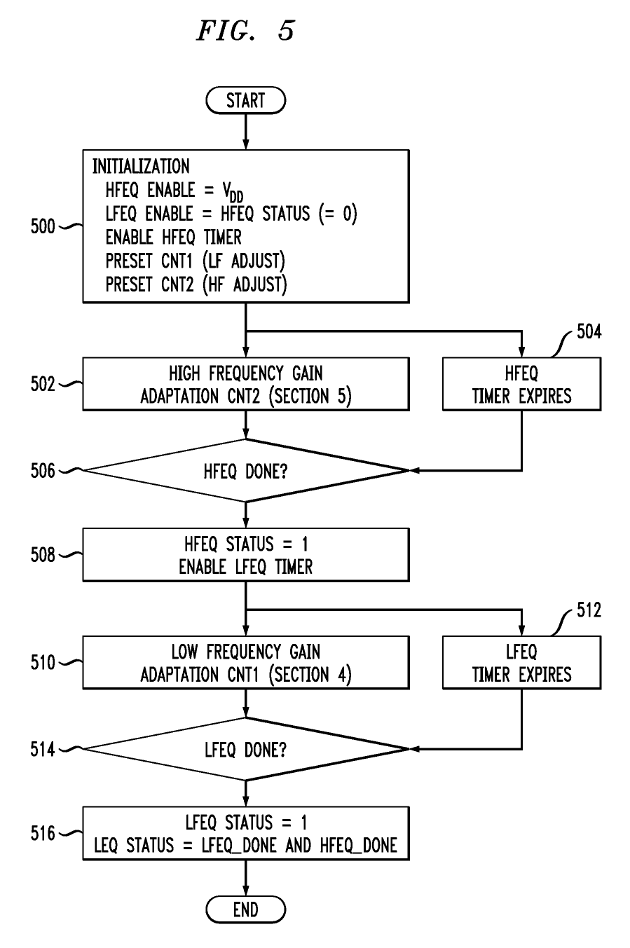

FIG. 5 illustrates the operation of the SHLA gain adaptation configuration. The process begins with initialization in step 500. As part of this initialization, the HFEQ enable signal is set to positive supply voltage V_{DD}, the LFEQ enable signal is set to the HFEQ status, the HFEQ timer is started, and the control signals CNT1 and CNT2 are adjusted to respective preset values. The HFEQ status is initially set to a logic zero value.

In step 502, the high frequency gain adaptation is performed using control signal CNT2 as described in greater detail in Section 5 below. Upon completion of the high frequency gain adaptation in step 502, or upon expiration of the HFEQ timer in step 504, the HFEQ portion of the process is determined to be complete in step 506, and the process then moves to step 508, where the HFEQ status is set to a logic one value, and the LFEQ timer is enabled.

In step 510, the low frequency gain adaptation is performed using control signal CNT1 as described in greater detail in Section 4 below. Upon completion of the low frequency gain adaptation in step 510, or upon expiration of the LFEQ timer in step 512, the LFEQ portion of the process is determined to be complete in step 514, and the process then moves to step 516, where the LFEQ status is set to a logic one value, and the LEQ status indicator is set to indicate that both the LFEQ and HFEQ portions of the process are complete.

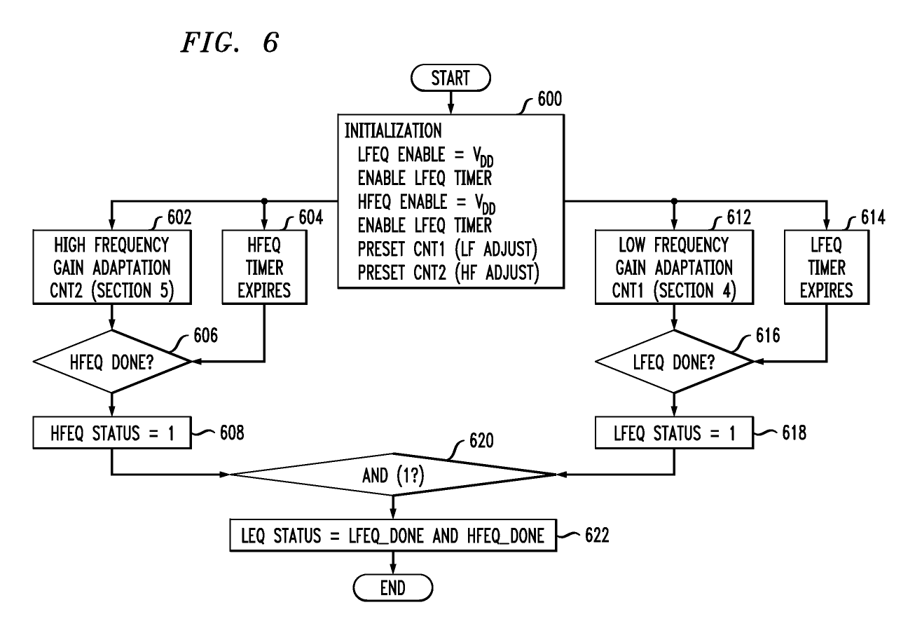

FIG. 6 illustrates the operation of the PA gain adaptation configuration. The process begins with initialization in step 600. As part of this initialization, the LFEQ and HFEQ enable signals are both set to positive supply voltage V_{DD}, the LFEQ and HFEQ timers are started, and the control signals CNT1 and CNT2 are adjusted to respective preset values.

In step 602, the high frequency gain adaptation is performed using control signal CNT2 as described in greater detail in Section 5 below. Upon completion of the high frequency gain adaptation in step 602, or upon expiration of the HFEQ timer in step 604, the HFEQ portion of the process is determined to be complete in step 606, and the HFEQ portion of the process then moves to step 608, where the HFEQ status is set to a logic one value.

The low frequency gain adaptation in FIG. 6 occurs in parallel with the high frequency gain adaptation. In step 612, the low frequency gain adaptation is performed using control signal CNT1 as described in greater detail in Section 4 below. Upon completion of the low frequency gain adaptation in step 612, or upon expiration of the LFEQ timer in step 614, the LFEQ portion of the process is determined to be complete in step 616, and the LFEQ portion of the process then moves to step 618, where the LFEQ status is set to a logic one value.

In step 620, a determination is made as to whether or not both the HFEQ status and the LFEQ status are equal to the logic one value. If both the HFEQ and LFEQ status are equal to the logic one value, the LEQ status indicator is set in step 622 to indicate that both the LFEQ and HFEQ portions of the process are complete.

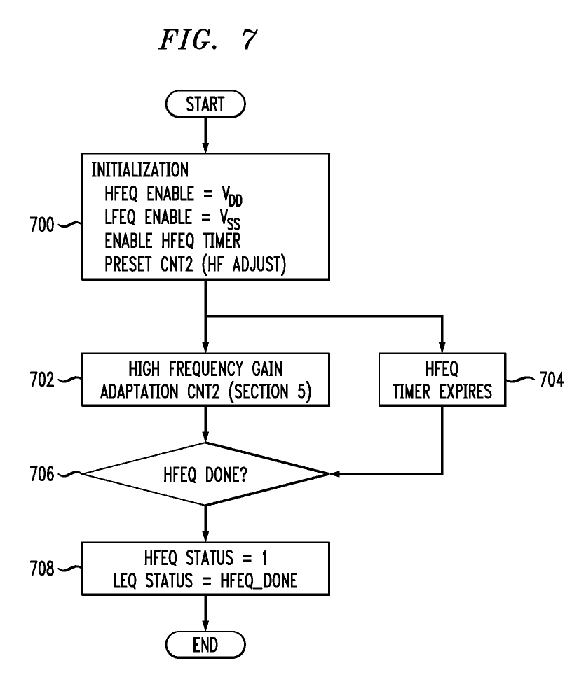

FIG. 7 illustrates the operation of the HA gain adaptation configuration. The process begins with initialization in step 700. As part of this initialization, the HFEQ enable signal is set to positive supply voltage V_{DD}, the LFEQ enable signal is set to a negative supply voltage V_{SS}, the HFEQ timer is started, and the control signal CNT2 is adjusted to a preset value.

In step 702, the high frequency gain adaptation is performed using control signal CNT2 as described in greater detail in Section 5 below. Upon completion of the high frequency gain adaptation in step 702, or upon expiration of the HFEQ timer in step 704, the HFEQ portion of the process is determined to be complete in step 706. The process then moves to step 708, where the HFEQ status is set to a logic one value, and the LEQ status indicator is set to indicate that the HFEQ portion of the process is complete.

It is to be appreciated that the particular process steps shown in FIGS. 4 through 7 are presented by way of illustrative example only, and may be varied in other embodiments. Also, as indicated previously, the equalization circuitry may support other gain adaptation configurations than those expressly described above.

### Section 2. RC-Tunable Analog Linear Equalizer

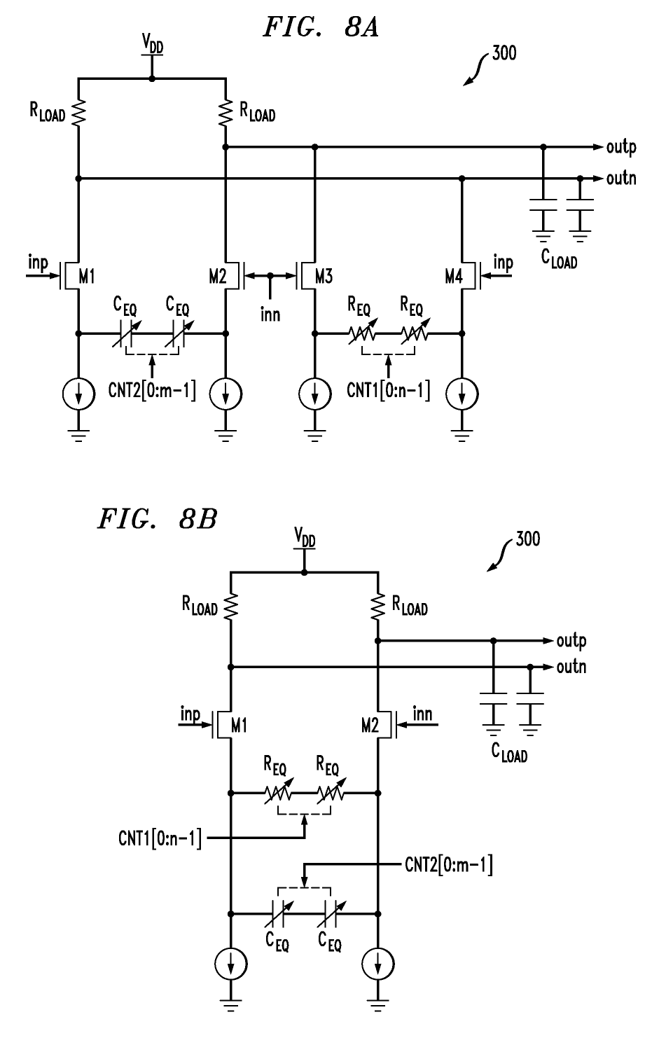

FIGS. 8A and 8B show illustrative embodiments of the LEQ 300 in the equalization circuitry 200 of FIG. 3. The LEQ 300 in these embodiments is implemented as an RC-tunable analog linear equalizer.

Referring initially to FIG. 8A, the LEQ 300 in this embodiment includes, among other elements, four N-type metal-oxide-semiconductor (MOS) transistors M1, M2, M3 and M4, two load resistors R_{LOAD}, two variable capacitance elements C_{EQ} and two variable resistance elements R_{EQ}. The transfer function of this LEQ can be approximated as:

$$\frac{{V}_{OUT}}{{V}_{IN}} = {G}_{LF} \frac{1 + {sR}_{EQ} {C}_{EQ}}{1 + {sR}_{LOAD} {C}_{LOAD}} ,$$

where V_{OUT}=Vₒᵤₜₚ−Vₒᵤₜₙ, V_{IN}=Vᵢₙₚ−Vᵢₙₙ, and

$${G}_{LF} = \frac{{R}_{LOAD}}{{R}_{EQ}}$$

is the low frequency or DC gain of the LEQ and is tunable through the variable resistance element R_{EQ}. The capacitance C_{LOAD} denotes a load capacitance of the LEQ as shown in FIG. 8A.

The LEQ 300 of FIG. 8B is similar to that of FIG. 8A, but includes only two MOS transistors M1 and M2, with the series combination of the variable two resistance elements R_{EQ} being arranged in parallel with the series combination of the two variable capacitance elements C_{EQ}.

Conventional aspects of the operation of LEQs similar to those shown in FIGS. 8A and 8B are described in the above-cited U.S. Patent Application Publication No. 2007/0018694.

In each of the LEQs 300 of FIGS. 8A and 8B, the n-bit low frequency gain adaptation control signal CNT1 is used to control the resistance values of the variable resistance elements R_{EQ}, and the m-bit high frequency gain adaptation control signal CNT2 is used to control the capacitance values of the variable capacitance elements C_{EQ}.

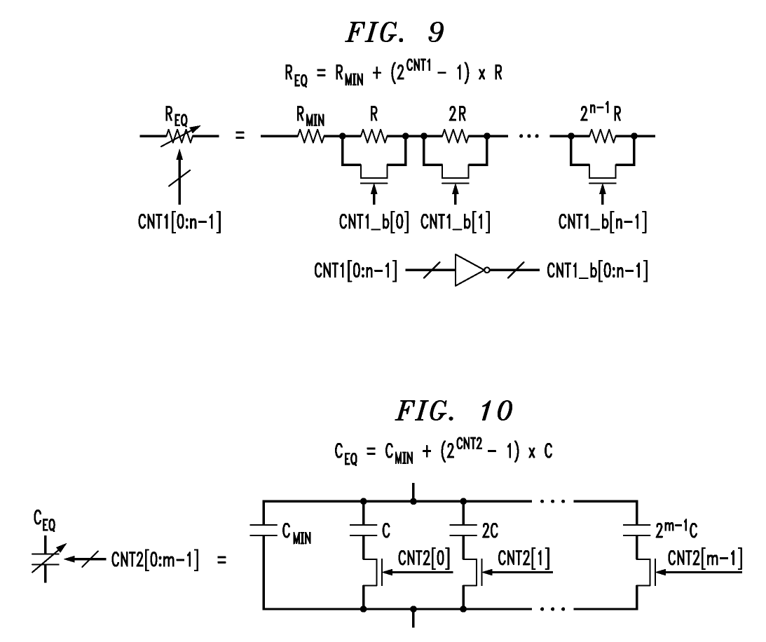

FIG. 9 shows the manner in which a given variable resistance element R_{EQ} is illustratively implemented as a binary weighted tunable resistor array controlled by the n-bit low frequency gain adaptation control signal CNT1. The bits of the control signal CNT1 are used to control respective switches arranged in parallel with respective resistors of the resistor array. The switches are implemented as MOS transistors, the gates of which receive respective inverted bits of the control signal CNT1 from an inverter 900. The resistors are arranged in series with one another, and other than an initial minimum resistance R_{MIN} have values that are weighted in a binary manner, with the first such resistor having a value R, the second having a value 2R, and so on, with the final resistor of the array having a value 2ⁿ⁻¹R.

The least significant bit of the control signal CNT1 controls the switch that is in parallel with the resistor having value R, and the most significant bit of the control signal CNT1 controls the switch that is in parallel with the resistor having value 2ⁿ⁻¹R. More particularly, if a given one of the bits of the control signal CNT1 has a logic zero value, its inverted value is a logic one, such that the switch is closed and the corresponding resistor is shorted out, thereby reducing the value of the variable resistance element R_{EQ}. Accordingly, the minimum value of the variable resistance element is R_{MIN}, when all switches of the resistor array are closed, and the maximum value of the variable resistance element is the sum of the individual resistor values, including R_{MIN}, when all switches of the resistor array are open. Resistance values between these minimum and maximum resistance values are achieved by appropriate setting of the bits of the control signal CNT1.

FIG. 10 shows the manner in which a given variable capacitance element C_{EQ} is illustratively implemented as a binary weighted tunable capacitor array controlled by the m-bit high frequency gain adaptation control signal CNT2. The bits of the control signal CNT2 are used to control respective MOS transistors arranged in series with respective capacitors of the capacitor array. The capacitors are arranged in parallel with one another, and other than an initial minimum capacitance C_{MIN} have values that are weighted in a binary manner, with the first such capacitor having a value C, the second having a value 2C, and so on, with the final capacitor of the capacitor array having a value 2^{m-1}C.

The least significant bit of the control signal CNT2 controls the MOS transistor that is in series with the capacitor having value C, and the most significant bit of the control signal CNT2 controls the MOS transistor that is in series with the capacitor having value 2^{m-1}C. More particularly, if a given one of the bits of the control signal CNT2 has a logic zero value, the associated N-type MOS transistor is off and the corresponding capacitor is open circuited, thereby reducing the value of the variable capacitance element C_{EQ}. Accordingly, the minimum value of the variable capacitance element is C_{MIN}, when all MOS transistors of the capacitor array are off, and the maximum value of the variable capacitance element is the sum of the individual capacitance values, including C_{MIN}, when all MOS transistors of the capacitor array are on. Capacitance values between these minimum and maximum capacitance values are achieved by appropriate setting of the bits of the control signal CNT2.

It should be noted that the use of binary weighted control as illustrated in FIGS. 9 and 10 is not a requirement of the present invention. Numerous other types of variable circuit elements can be used in alternative embodiments. For example, other types of unidirectional control may be used in place of binary weighted control.

FIG. 11 shows frequency response curves for an exemplary implementation of LEQ 300 configured as shown in FIG. 8B. In this implementation, there are three bits of resistance control for low frequency gain adaptation and four bits of capacitance control for high frequency gain adaptation, such that n=3 and m=4. The figure shows the frequency responses associated with each of the 16 possible values of the high frequency gain adaptation control signal CNT2 for each of the eight possible values of the low frequency gain adaptation control signal CNT1. Similar frequency response curves are associated with the FIG. 8A version of the LEQ 300, as will be appreciated by those skilled in the art.

It should be understood that the particular LEQ circuitry and associated control signal formats described above are examples only, and alternative embodiments may utilize other types of LEQ circuitry and control signal formats. For example, the LEQ 300 may be replaced with another type of analog equalizer. Alternative analog equalizers suitable for use in embodiments of the invention need not be linear, but will generally exhibit a monotonic response to one or more applied control signals.

Section 3. Approximate Frequency Separation through Pattern Identification

As noted previously, the equalization circuitry 300 in the illustrative embodiment is configured to achieve approximate frequency separation between low frequency and high frequency gain adaptation through the use of pattern identification. Such an approach is advantageous in that it avoids the need for costly circuit components such as low-pass and high-pass filters.

It is known that frequency information is embedded in a non-return-to-zero (NRZ) serial data stream in the form of signal transitions between logic one and zero values. For example, a high transition density data stream contains more high frequency content than a low transition density data stream. Similarly, a low transition density data stream contains more low frequency content than a high transition density data stream. See, for example, the compliance jitter tolerance (CJT) test patterns specified in the above-noted Fibre Channel standards.

The present embodiment utilizes pattern identification rules to approximately classify portions of a received data stream based on frequency content and to control selection of low frequency or high frequency gain adaptation for those portions.

The pattern identification rules in this embodiment include a high frequency pattern identification exact rule, two high frequency pattern identification approximate rules, a low frequency pattern identification exact rule, and two low frequency pattern identification approximate rules. These pattern identification rules are defined as follows:

High frequency pattern identification exact rule: A single pulse is a bit pattern with high frequency content. Signal transitions occur before and after the signaling bit. The bit pattern is matched to a bit sequence of one or more preceding bits of the same value, one signaling bit of the opposite value, and one or more succeeding bits of the same value as the preceding bits.

High frequency pattern identification approximate rule 1: A bit with the opposite value as one or more preceding bits is an approximate bit pattern with high frequency content. There is a signal transition at the leading edge of the signaling bit.

High frequency pattern identification approximate rule 2: A bit with the opposite value as one or more succeeding bits is an approximate bit pattern with high frequency content. There is a signal transition at the trailing edge of the signaling bit.

Low frequency pattern identification exact rule: A bit with the same value as one or more preceding bits and one or more succeeding bits is an exact bit pattern with low frequency content. There are no signal transitions at the leading edge and the trailing edge of the signaling bit.

Low frequency pattern identification approximate rule 1: A bit with the same value as one or more preceding bits is an approximate bit pattern with low frequency content. There is no signal transition at the leading edge of the signaling bit.

Low frequency pattern identification approximate rule 2: A bit with the same value as one or more succeeding bits is an approximate bit pattern with low frequency content. There is no signal transition at the trailing edge of the signaling bit.

In general, high or low frequency pattern identification approximate rule 1 has the simplest implementation since it only requires checking of the previously received bits.

Although these are the rules used to identify patterns for selection of low frequency or high frequency gain adaptation in the present embodiment, other embodiments may utilize only a subset of these rules, or one or more alternative rules. For example, it is possible to use just one of the three rules in each of the sets above.

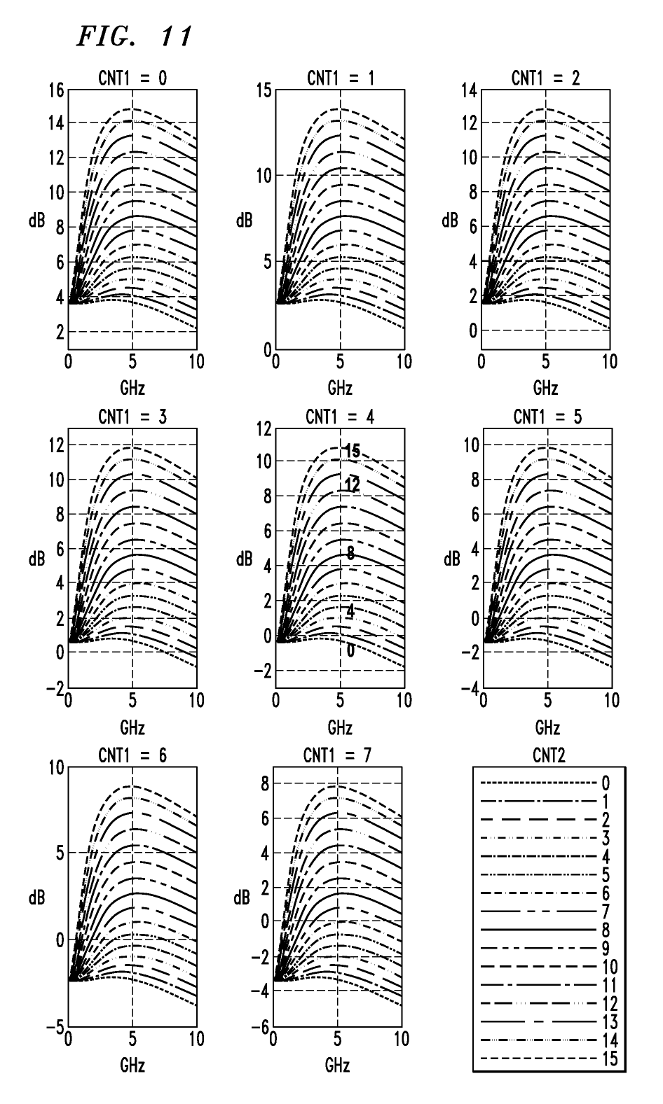

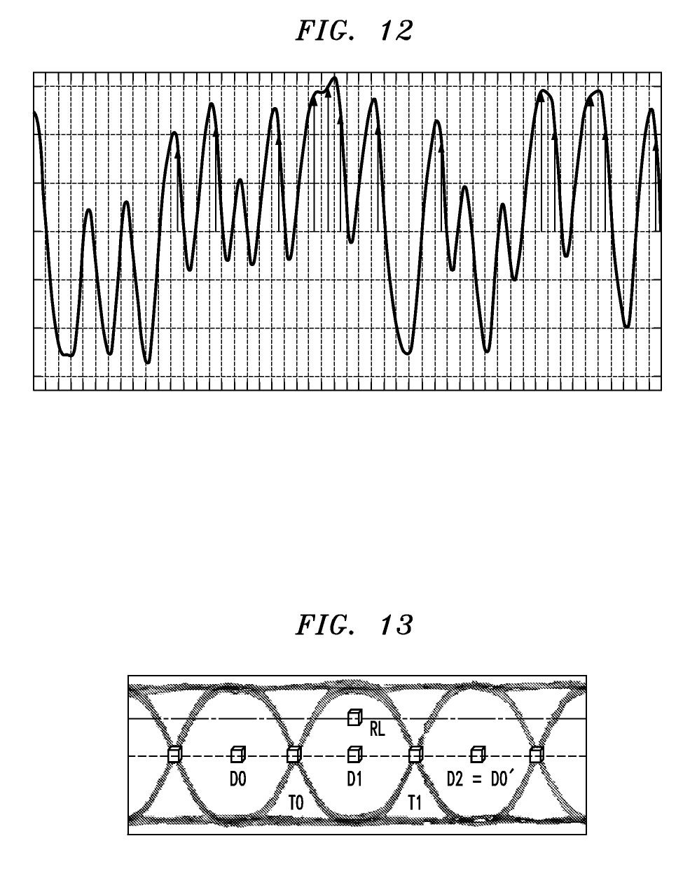

FIG. 12 illustrates the application of the above-defined low frequency pattern identification approximate rule 1 to identify low frequency signaling bits in an exemplary pseudorandom 27-1 bit pattern. The positive polarity bits (+1 values) identified using this particular low frequency approximate rule are marked in the figure by vertical pointed arrows originating from a 0 volt offset level. Only the positive polarity bits are shown in FIG. 12, as determined using a positive polarity process to be described below in conjunction with the flow diagram of FIG. 14. Negative polarity bits (−1 values) which satisfy the low frequency approximate rule are not expressly identified in FIG. 12, but may be determined using a negative polarity process to be described below in conjunction with the flow diagram of FIG. 15.

It should be noted that a given signaling bit may satisfy both a low frequency approximate rule and a high frequency approximate rule. In such a situation, one may flexibly determine to apply both low and high frequency adaptation, either low or high frequency adaptation, or neither low nor high frequency adaptation. The latter approach is also referred to herein as “exclusion.”

FIG. 13 illustrates the operation of eye latch array 302 of the FIG. 3 equalization circuitry 200 in an illustrative embodiment. This particular eye latch array is assumed to implement a 2-UI sampling arrangement, as previously noted, although other sampling arrangements can be used. Latches of the eye latch array in this embodiment include two data latches D0 and D1, two transition latches T0 and T1, and a single roaming latch RL, which are shown in the figure as being superimposed on corresponding portions of an exemplary serial data stream.

The data latches D0 and D1 are used for the first and second UIs, respectively. Similarly, the transition latches T0 and T1 are also used for the respective first and second UIs. The data latches and transition latches have a zero-volt amplitude offset as indicated in the figure, and a given data latch is arranged 90 degrees apart in phase relative to its adjacent transition latches. Both the phase and amplitude offset of the roaming latch RL are adjustable to assist in eye capture. Data latch D2 represents a subsequent use of data latch D0 for another portion of the serial data stream and is therefore also identified as D0′ in the figure.

In a typical implementation, the latches of the latch array are interconnected in parallel, with the data input of each latch being connected to the output of the LEQ 300, and each latch being clocked by a clock signal having a different phase. More particularly, the clock signals applied to the various latches are separated in phase by 90 degrees relative to one another. Each latch therefore captures the same input signal but at different points in time. The term “latch array” as used herein is intended to be construed broadly so as to encompass such parallel arrangements of multiple data and transition latches, as well as other arrangements of latches.

Alternative embodiments of the eye latch array 302 may include different numbers of data, transition and roaming latches, as will be appreciated by those skilled in the art. For example, as mentioned previously herein, the eye latch array in the FIG. 13 embodiment is a bang-bang type eye latch array, but other embodiments can utilize other types of latch arrays including, for example, baud rate type latch arrays which do not require the use of transition latches.

### Section 4. Low Frequency Gain Adaptation Flow

An exemplary low frequency gain adaptation will now be described in greater detail with reference to the flow diagrams of FIGS. 14 and 15. There are two different types of low frequency gain adaptation that may be used in the present embodiment, depending on bit sequence polarity. More particularly, these two types are a positive polarity flow (PPF) shown in FIG. 14 and a negative polarity flow (NPF) shown in FIG. 15. The two low frequency adaptation flows provide enhanced flexibility in receiver design, and can be applied serially, in parallel or individually based on a given receiver architecture. Experimental results to be discussed below indicate that such low frequency gain adaptations perform well with an eye latch array having a single roaming latch as illustrated in FIG. 13.

Referring now to FIG. 14, the PPF process begins in step 1400 by initializing the voltage offset of the roaming latch RL to a positive value +ΔV, and setting direction and status variables to logic zero values. In step 1402, the data polarity is determined. If the polarity is negative (−1), the process remains in step 1402. If the polarity is positive (+1), a determination is made in step 1404 as to whether a check of one or more of the low frequency pattern identification rules indicates the presence of low frequency content. It should be noted that only one such rule need be checked, although this step may involve checking multiple rules. If one or more of the rules when checked is indicative of the presence of low frequency content, the process moves to step 1406, and otherwise returns to step 1402. In step 1406, a roaming latch value R_{S} is updated and an average roaming latch value R_{avg} is determined as the sign of the sum of R_{S} and a specified size, to the extent the sum is much greater than a specified step.

The difference between the preset value of the low frequency adaptation control signal CNT1 and the average roaming latch value R_{avg} is determined in step 1408. If this difference is within a specified range, the process moves to step 1410 to determine whether the direction is the same as previously set, initially a logic zero value. If the direction is the same, it is updated to the inverse of R_{avg}, and the control signal CNT1 is decremented by R_{avg}, as indicated in step 1412, and the process then returns to step 1402 to process additional data. If the direction is not the same, R_{avg} is checked in step 1414 and, if equal to −1, the direction is updated to R_{avg} and the control signal CNT1 is decremented by R_{avg}, as indicated in step 1416, and the status is then set to a logic one value in step 1418. If R_{avg} when checked in step 1414 is equal to +1, the status is set to a logic one value in step 1418, and the process ends. If the difference determined in step 1408 is outside of the specified range, the process moves directly to step 1418 to update the status as indicated.

The size variable in step 1406 refers to a maximum number of bits to be accumulated, and thus controls the feedback duration. It may be thought of as a type of timer. As indicated in step 1406, the roaming latch value R_{S} can take on values of +1 or −1. Assume the size variable is set to 100, indicating that 100 bits are to be accumulated. If the number of +1 values and the number of −1 values are in balance, with 50 of each value, the average value will be zero. However, if the numbers of values are unbalanced, with for instance 70 of the +1 values and 30 of the −1 values, then the average value is +40. This represents an over-equalized condition, and the control signal applied to the LEQ 300 is adjusted accordingly to try to achieve a balance between the +1 and −1 values. Generally, a larger size increases measurement accuracy, but also slows down the update cycle.

The step variable in step 1406 provides a guard range for measurement values. It is a type of divide function and if limited to factors of two it can be implemented efficiently by simply shifting bits. By way of example, if step=4, measurements comprising values of +3, +1, −2 and so on will all yield an R_{avg} value of zero after dividing by the step, and will be considered to indicate proper equalization. However, if the measurement falls outside of the specified step range, the process will adjust the control signal accordingly.

The final gain reverse in steps 1414 and 1416 is optional and may be bypassed as indicated by the dashed line in the figure. This gain reverse is applied to ensure that the LEQ 300 does not introduce excessive high frequency gain.

As noted previously, FIG. 15 shows the NPF process. The NPF process begins in step 1500 by initializing the voltage offset of the roaming latch RL to a negative value −ΔV, and setting direction and status variables to logic zero values. In step 1502, the data polarity is determined. If the polarity is positive (+1), the process remains in step 1502. If the polarity is negative (−1), a determination is made in step 1504 as to whether a check of one or more of the low frequency pattern identification rules indicates the presence of low frequency content. Again, only one such rule need be checked, although this step may involve checking multiple rules. If one or more of the rules when checked is indicative of the presence of low frequency content, the process moves to step 1506, and otherwise returns to step 1502. In step 1506, a roaming latch value R_{S} is updated and the average roaming latch value R_{avg} is determined as the sign of the sum of R_{S} and a specified size, to the extent the sum is much greater than a specified step.

The sum of the preset value of the low frequency adaptation control signal CNT1 and the average roaming latch value R_{avg} is determined in step 1508. If this difference is within a specified range, the process moves to step 1510 to determine whether the direction is the same as previously set, initially a logic zero value. If the direction is the same, it is updated to the value of R_{avg}, and the control signal CNT1 is incremented by R_{avg}, as indicated in step 1512, and the process then returns to step 1502 to process additional data. If the direction is not the same, R_{avg} is checked in step 1514 and, if equal to +1, the direction is updated to the inverse of R_{avg} and the control signal CNT1 is incremented by R_{avg}, as indicated in step 1516, and the status is then set to a logic one value in step 1518. If R_{avg} when checked in step 1514 is equal to −1, the status is set to a logic one value in step 1518, and the process ends. If the difference determined in step 1508 is outside of the specified range, the process moves directly to step 1518 to update the status as indicated. As in the FIG. 14 process, the final gain reverse in steps 1514 and 1516 is optional and may be bypassed as indicated by the dashed line in the figure.

The low frequency gain adaptation in FIGS. 14 and 15 uses a 1-bit sign update approach. Alternative embodiments may utilize a multi-bit update approach by using accumulated sum information. A multi-bit approach has the advantage of faster adaptation rate at the expense of a more complex design.

A given embodiment may involve performing both the PPF and the NPF. For example, these two processes may be performed in series. The difference in the gain control values from these two polarities may indicate a DC offset condition when a DC-balanced pattern is received for a sufficiently long observation window. This DC offset can be further optimized away until gain control values from both polarities agree with each other. Alternatively, an average of the two gain control values may be used.

It is also possible to perform the PPF and the NPF in parallel. This can be achieved by configuring the eye latch array 302 to include dual roaming latches (RL+ and RL−). Such an arrangement would generally provide faster convergence of the low frequency gain adaptation.

### Section 5. High Frequency Gain Adaptation Flow

An exemplary high frequency gain adaptation will now be described in greater detail with reference to the flow diagram of FIG. 16. For this exemplary high frequency adaptation flow, the transition latches T0 and T1 are used to detect early or late edge positions. The roaming latch RL is not used in this flow. The flow diagram shows the high frequency adaptation flow for the data bit associated with data latch D1 in FIG. 13. A similar process can be applied to other data bits such as that associated with data latch D0.

The high frequency gain adaptation process begins in step 1600 by setting direction and status variables to logic zero values. In step 1602, a determination is made as to whether a check of one or more of the above-noted high frequency pattern identification rules indicates the presence of high frequency content. Depending on which of the rules when checked indicates the presence of high frequency content, the process moves to either step 1604, step 1606 or step 1608, which correspond to the exact rule and the first and second approximate rules, respectively. A variable W is updated in a different way in each of these steps, depending on the contents of the data latch D1 and the transition latches T0 and T1. More specifically, in step 1604, W is set to +1 if the sign of T0 and T1 is not equal to that of D1, to −1 if the sign of T0 and T1 is equal to D1, and to 0 otherwise. In step 1606, W is set to +1 if the sign of T0 is not equal to that of D1, and to −1 if the sign of T0 is equal to that of D1. Similarly, in step 1608, W is set to +1 if the sign of T1 is not equal to that of D1, and to −1 if the sign of T1 is equal to that of D1. In step 1610, an average value W_{avg} is determined as the sign of the sum of W and a specified size, to the extent the sum is much greater than a specified step.

The sum of the preset value of the low frequency adaptation control signal CNT2 and the average value W_{avg} is determined in step 1612. If this difference is within a specified range, the process moves to step 1614 to determine whether the direction is the same as previously set, initially a logic zero value. If the direction is the same, it is updated to the value of W_{avg}, and the control signal CNT2 is incremented by W_{avg}, as indicated in step 1616, and the process then returns to step 1602 to process additional data. If the direction is not the same, W_{avg} is checked in step 1618 and, if equal to −1, the direction is updated to the inverse of W_{avg} and the control signal CNT2 is incremented by W_{avg}, as indicated in step 1620, and the status is then set to a logic one value in step 1622. If W_{avg} when checked in step 1618 is equal to +1, the status is set to a logic one value in step 1622, and the process ends. If the difference determined in step 1612 is outside of the specified range, the process moves directly to step 1622 to update the status as indicated. As in the FIG. 14 and FIG. 15 processes, the final gain reverse in steps 1614 and 1618 is optional and may be bypassed as indicated by the dashed line in the figure.

The high frequency gain adaptation in FIG. 16, like the low frequency gain adaptation of FIGS. 14 and 15, uses a 1-bit sign update approach. Again, alternative embodiments may utilize a multi-bit update approach by using accumulated sum information.

### Section 6. Experimental Results

Four exemplary use cases were tested to demonstrate the performance advantages of illustrative embodiments of the present invention. These cases are denoted Case 1 through Case 4 in the following description.

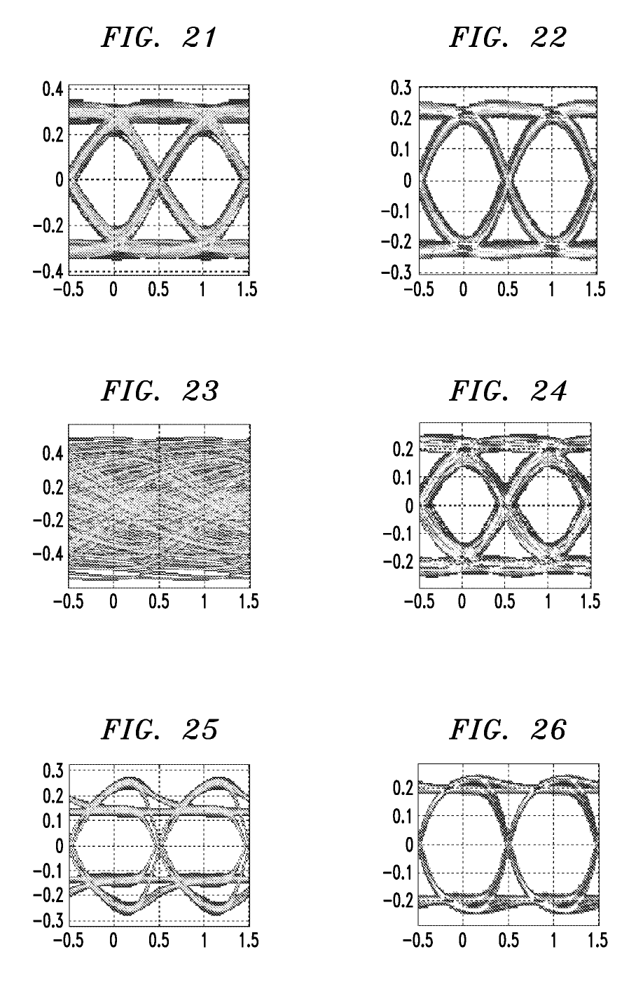

FIGS. 17-26 are eye diagrams associated with the various cases, with FIGS. 17-20 corresponding to Case 1, FIGS. 21-22 corresponding to Case 2, FIGS. 23-24 corresponding to Case 3, and FIGS. 25-26 corresponding to Case 4.

Each of these cases illustrates the eye diagram improvement attributable to use of an embodiment of the serial low frequency and high frequency adaptation (SLHA) of FIG. 4.

Case 1 illustrates application of SLHA to an under-equalized input data signal having a partially-closed eye diagram.

FIG. 17 shows the eye diagram of the data signal at the receiver input. It is apparent that the eye is partially closed.

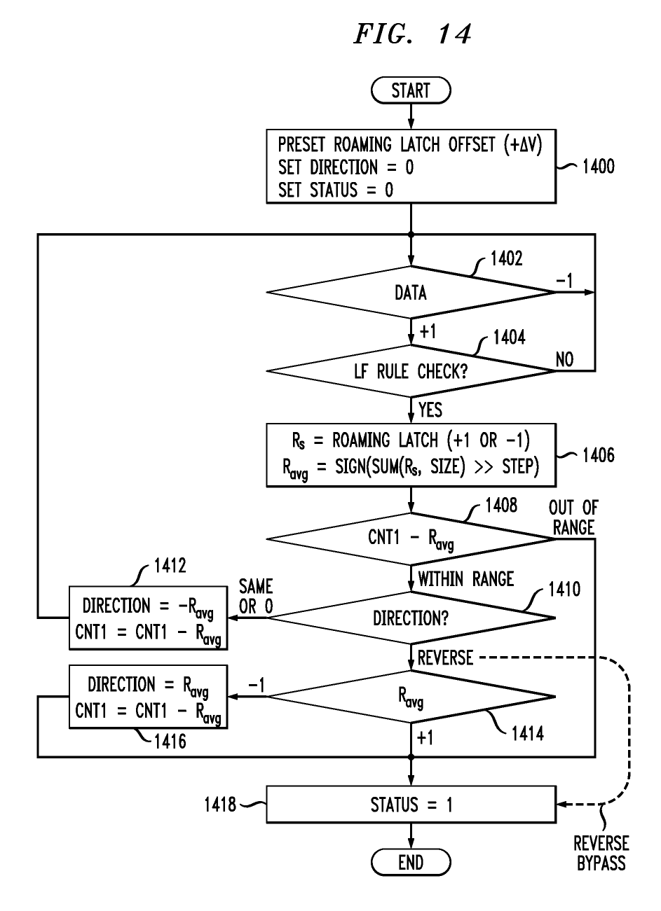

FIG. 18 shows the eye diagram at the output of the LEQ using default values of 3 for both the CNT1 and CNT2 control signals.

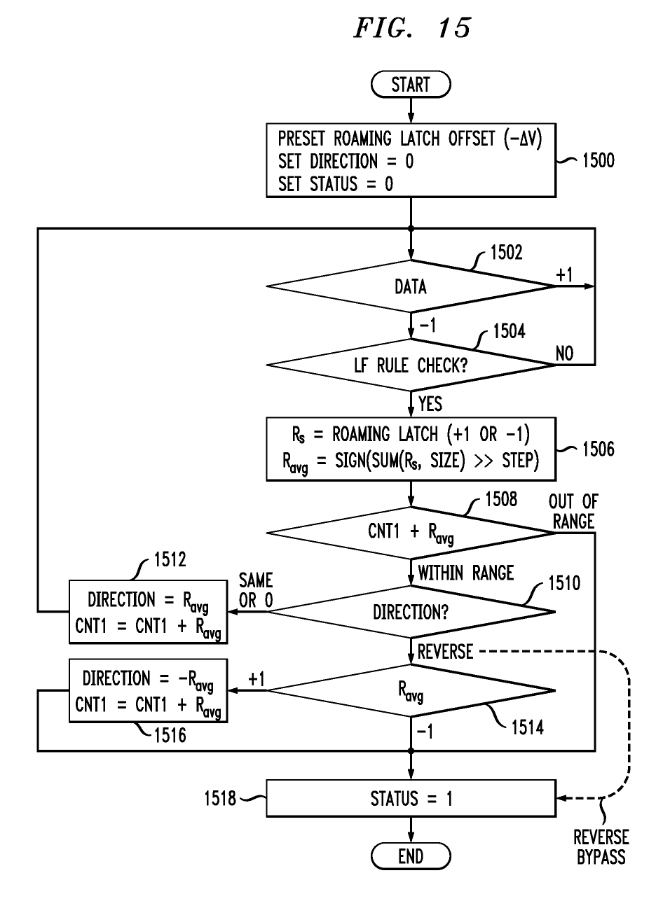

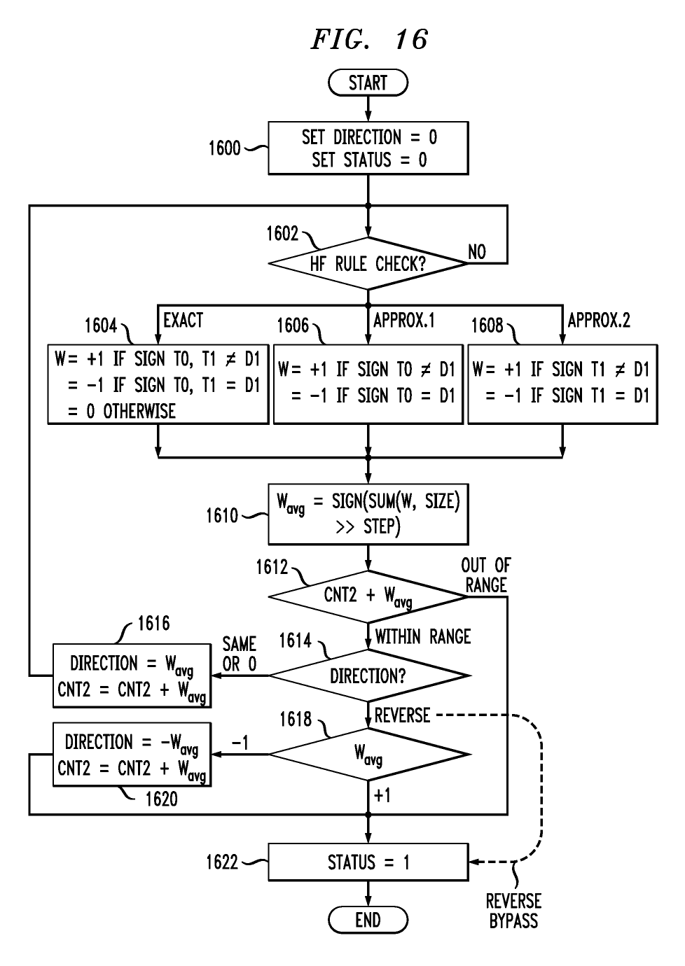

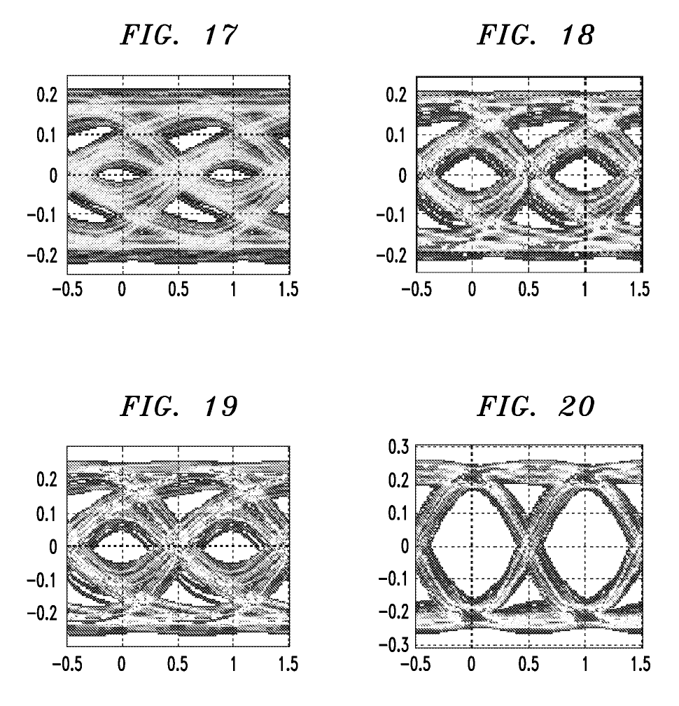

FIG. 19 shows the eye diagram at the output of the LEQ after the performance of the low frequency gain adaptation portion of the SLHA. The roaming latch offset ΔV was set to 240 millivolts. The CNT1 signal adapts from its default value of 3 to a value of 1 using the low frequency pattern identification approximate rule 1 in the positive polarity flow (PPF) of FIG. 14. There is a noticeable envelope amplitude increase.

FIG. 20 shows the eye diagram at the output of the LEQ after the performance of the high frequency gain adaptation portion of the SLHA. The CNT2 signal adapts from its default value of 3 to a value of 12 using the high frequency pattern identification exact rule.

Case 2 illustrates application of SLHA to an input data signal with an open eye diagram.

FIG. 21 shows the eye diagram of the data signal at the receiver input.

FIG. 22 shows the eye diagram at the output of the LEQ after performance of both the low frequency and high frequency portions of the SLHA. The CNT1 and CNT2 control signals adapt from their initial default values of 3 to final values of 4.

Case 3 illustrates application of SLHA to an under-equalized input data signal having a completely closed eye diagram.

FIG. 23 shows the eye diagram of the data signal at the receiver input. It is apparent that the eye is completely closed.

FIG. 24 shows the eye diagram at the output of the LEQ after performance of both the low frequency and high frequency portions of the SLHA. The CNT1 and CNT2 control signals adapt from their initial default values of 3 to final values of 7 and 15, respectively.

Case 4 illustrates application of SLHA to an over-equalized input data signal.

FIG. 25 shows the eye diagram of the data signal at the receiver input.

FIG. 26 shows the eye diagram at the output of the LEQ after performance of both the low frequency and high frequency portions of the SLHA. The CNT1 and CNT2 control signals adapt from their initial default values of 3 to final values of 0.

Although the results above are illustrated for an SLHA embodiment, it is expected that similar improvements in data signal eye diagrams will be achieved in SHLA embodiments as well as other embodiments.

Illustrative embodiments of the invention as described above provide a number of significant advantages over conventional techniques. For example, these embodiments are self-adaptive and therefore avoid the costs and performance limitations commonly associated with use of manual tuning of LEQ parameters. The self-adaptive equalization provided in the illustrative embodiments can therefore allow a given SerDes or other communication device to operate at a higher data rate than would otherwise be possible. The use of approximate frequency separation based on pattern recognition is simpler and less costly than approaches that rely on separation of frequency bands by filtering. Also, the use of independent low frequency and high frequency gain adaptation loops provides a flexible implementation that can be readily implemented in a communication device integrated circuit.

A receiver with equalization circuitry in accordance with the invention may be implemented in the form of one or more integrated circuit devices suitable for installation on a board or card of an otherwise conventional communication device.

In a given such integrated circuit implementation, identical die are typically formed in a repeated pattern on a surface of a semiconductor wafer. Each die includes at least a portion of testing system as described herein, and may include other structures or circuits. The individual die are cut or diced from the wafer, then packaged as an integrated circuit. One skilled in the art would know how to dice wafers and package die to produce integrated circuits. Integrated circuits so manufactured are considered part of this invention.

It should again be emphasized that the particular exemplary receiver configurations shown in FIGS. 2, 3, 8-10 and 13 and the particular exemplary process steps of FIGS. 4-7 and 14-16 may be varied in other embodiments. For example, different types of equalization circuitry may be used to implement gain adaptation techniques as described herein.

These and numerous other alternative embodiments within the scope of the following claims will be readily apparent to those skilled in the art.

What is claimed is:

1. An apparatus comprising:
equalization circuitry implementing at least first and second gain adaptation loops associated with respective first and second frequency bands;
wherein the equalization circuitry is configured to identify a pattern in a portion of a received serial data stream, and to perform gain adaptation utilizing a particular one of the gain adaptation loops responsive to the identified pattern.

2. The apparatus of claim 1 wherein the equalization circuitry comprises:
an equalizer configured to receive the serial data stream;
a latch array having an input coupled to an output of the equalizer;
first and second gain adaptation elements arranged within the respective first and second gain adaptation loops and coupled between an output of the latch array and respective control inputs of the equalizer; and
selection circuitry configured to selectively activate at least one of the first and second gain adaptation elements responsive to a particular operating mode of the equalization circuitry.

3. The apparatus of claim 1 wherein the first gain adaptation loop comprises a low frequency gain adaptation loop and the second gain adaptation loop comprises a high frequency gain adaptation loop.

4. The apparatus of claim 2 wherein the equalization circuitry is operable in a serial equalization mode in which the first and second gain adaptation elements are activated in a particular serial order.

5. The apparatus of claim 4 wherein the equalization circuitry is operable in at least two distinct serial equalization modes comprising:
a first serial equalization mode in which the first gain adaptation element is activated to allow the first gain adaptation loop to perform gain adaptation for the first frequency band prior to the second gain activation element being activated to allow the second gain adaptation loop to perform gain adaptation for the second frequency band; and
a second serial equalization mode in which the second gain adaptation element is activated to allow the second gain adaptation loop to perform gain adaptation for the second frequency band prior to the first gain activation element being activated to allow the first gain adaptation loop to perform gain adaptation for the first frequency band.

6. The apparatus of claim 2 wherein the equalization circuitry is operable in a parallel equalization mode in which the first gain adaptation element is activated to allow the first gain adaptation loop to perform gain adaptation for the first frequency band substantially simultaneously with the second gain activation element being activated to allow the second gain adaptation loop to perform gain adaptation for the second frequency band.

7. The apparatus of claim 2 wherein the equalization circuitry is operable in a single-band equalization mode in which only a designated one of the first and second gain adaptation elements is activated to allow its corresponding gain adaptation loop to perform gain adaptation for the associated frequency band.

8. The apparatus of claim 2 wherein the first and second gain adaptation elements comprise respective first and second gain adaptation state machines.

9. The apparatus of claim 2 wherein the first and second gain equalization elements apply respective first and second sets of pattern identification rules to one or more portions of the serial data stream as stored in the latch array in order to detect patterns associated with the respective first and second frequency bands.

10. The apparatus of claim 9 wherein the first set of rules utilized by the first gain adaptation element to detect patterns associated with the first frequency band comprises at least one of a low frequency exact rule, a first low frequency approximate rule, and a second low frequency approximate rule.

11. The apparatus of claim 9 wherein the second set of rules utilized by the second gain adaptation element to detect patterns associated with the second frequency band comprises at least one of a high frequency exact rule, a first high frequency approximate rule, and a second low frequency approximate rule.

12. The apparatus of claim 2 wherein the equalizer comprises a linear equalizer having a first variable element controlled by a first control signal generated by the first gain adaptation element and a second variable element controlled by a second control signal generated by the second gain adaptation element.

13. The apparatus of claim 12 wherein the first variable element comprises one or more variable resistance elements and the second variable element comprises one or more variable capacitance elements.

14. The apparatus of claim 12 wherein at least one of the first and second variable elements is implemented as one or more binary weighted arrays of resistors or capacitors.

15. The apparatus of claim 1 further comprising:
a processor; and
a memory coupled to the processor and configured to store one or more parameters of the first and second gain adaptation loops;
wherein at least a portion of the equalization circuitry is operated under control of the processor.

16. The apparatus of claim 1 further comprising a processor that implements at least a portion of the equalization circuitry.

17. A method of receiver equalization, the method comprising the steps of:
identifying a pattern in a portion of a received serial data stream; and
performing gain adaptation for the receiver utilizing a particular one of a plurality of gain adaptation loops associated with respective frequency bands responsive to the identified pattern.

18. The method of claim 17 wherein the performing step further comprises performing the gain adaptation utilizing a low frequency gain adaptation loop if the detected pattern is of a first type generally associated with a low frequency band and performing the gain adaptation utilizing a high frequency gain adaptation loop if the detected pattern is of a second type generally associated with a high frequency band.

19. The method of claim 17 wherein the step of identifying the pattern further comprises the step of applying respective first and second sets of pattern identification rules to the portion of the received serial data stream in order to detect patterns associated with the respective first and second frequency bands.

20. A computer program product having computer program code embodied therein for use in receiver equalization, wherein the computer program code when executed in a receiver causes the receiver to perform the steps of:
identifying a pattern in a portion of a received serial data stream; and
performing gain adaptation for the receiver utilizing a particular one of a plurality of gain adaptation loops associated with respective frequency bands responsive to the identified pattern.
